(19) United States
(12) Patent Application Publication
(10) Pub. No.: US 2026/0371978 A1
(43) Pub. Date: Nov. 19, 2026

(54) METHOD FOR ATTACHING AND DETACHING WAFERS DURING INTEGRATED CIRCUIT MANUFACTURING

(71) Applicant: PulseForge, Inc., Austin, TX (US)

(72) Inventors: Vikram Shreeshail Turkani, Austin, TX (US); Jonathan Gibson, Steamboat Springs, CO (US)

(21) Appl. No.: 19/680,489

(22) Filed: May 18, 2026

Related U.S. Application Data
(60) Provisional application No. 63/807,366, filed on May 16, 2025.

(51) Int. Cl. H10P 56/00; B32B 43/00; H10P 72/70

(52) U.S. Cl. CPC H10P 56/00; B32B 43/006; H10P 72/7426; B32B 2457/14

(57) ABSTRACT

A carrier and methods for using a carrier for attaching and detaching electronics structures during manufacturing processes are disclosed. The carrier is formed by depositing a light-absorbing layer on a substantially transparent carrier body. A light-curable adhesive is deposited on an electronics structure and/or the carrier. The electronics structure is then placed on the carrier to form a carrier stack. Next, light is directed through the carrier and the light-absorbing layer in order to cure the light-curable adhesive. After the electronics structure has been processed, light is transmitted through the carrier body in order to detach the electronics structure from the carrier.

### CROSS-REFERENCE TO RELATED APPLICATIONS

This application claims the benefit of U.S. Provisional Patent Application No. 63/807,366, filed May 16, 2025, which is hereby incorporated herein by reference in its entirety.

### TECHNICAL FIELD

The present disclosure relates to electronics structure (e.g., integrated circuit) manufacturing in general, and, in particular, to a method for attaching and detaching wafers (more broadly, electronics structures) during integrated circuit manufacturing.

### BACKGROUND

During integrated circuit manufacturing, one or more processing steps, such as a thinning step, can be performed on each semiconductor wafer having integrated circuits in order to reduce the thickness of the semiconductor wafer. The semiconductor wafer is typically bonded to a rigid carrier prior to the processing. Existing approaches for attaching a semiconductor wafer to a carrier involve the usage of an adhesive placed directly between the semiconductor wafer and the carrier. After all the required backside processing (e.g., back grinding) has been completed on the semiconductor wafer, the processed semiconductor wafer is then detached from the carrier so that it can progress to its next intended destination.

The present disclosure provides an improved method and related apparatus for attaching and detaching electronics structures (e.g., wafer substrates) during integrated circuit manufacturing.

### SUMMARY

In one aspect, a method for processing electronics structures comprises providing a carrier stack. The carrier stack includes a carrier comprising a substantially transparent carrier body. The carrier stack also includes a light-absorbing layer carried by the carrier body. The light-absorbing layer comprises a first light-absorbing material that is at least partially transmissive to light in a wavelength range. The light-absorbing layer comprises a second light-absorbing material that is at least partially transmissive to light in the wavelength range. The first light-absorbing material and the second light-absorbing material are configured to absorb light to generate heat. The carrier stack also includes an electronics structure temporarily bonded to the carrier stack with a curable adhesive. The method additional comprises directing a pulse of light through the carrier body to facilitate separation of the electronics structure and carrier body by generating heat in the light-absorbing layer. The second light-absorbing material is configured to cause the light to reflect within the light-absorbing layer to facilitate heat generation.

In another aspect, a method for processing electronics structures comprises providing a carrier, the carrier comprising a substantially transparent carrier body and a light-absorbing layer carried by the carrier body. The light-absorbing layer comprises a first light-absorbing material that is at least partially transmissive to light in a range of light wavelengths. The light-absorbing layer comprises a second light-absorbing material that is at least partially transmissive to light in the range of light wavelengths. The method further includes disposing a light-curable adhesive between the light-absorbing layer and a surface of an electronics structure. The method further includes curing the light-curable adhesive by directing light in the range through the carrier body and the light-absorbing layer. The light-absorbing layer is configured to cause at least a portion of a pulse of light transmitted through the carrier body to reflect within the light-absorbing layer to facilitate heat generation in the light-absorbing layer.

In yet another aspect, an electronics structure temporary carrier comprises a substantially transparent carrier body and a light-absorbing layer carried by the carrier body. The light-absorbing layer transmits 0.1% to 20% of light within a wavelength range of about 150 nm to about 500 nm. The light-absorbing layer comprises a first sub-layer comprising a first light-absorbing material that is at least partially transmissive to light in the UV spectrum. The light-absorbing layer comprises a second sub-layer comprising a second light-absorbing material different from the first light-absorbing material, the first sub-layer defining a first surface facing the carrier body and a second surface facing the second sub-layer. The second light-absorbing material is configured to cause a pulse of light traveling through the carrier body and the first sub-layer that is outside the UV spectrum to reflect within the light-absorbing layer to facilitate heat generation.

In another aspect, a method of forming a carrier adapted for temporarily carrying an electronics structure for manufacturing comprises providing a substantially transparent carrier body. The method further comprises depositing a first sub-layer to be carried by carrier body. The first sub-layer comprises a first light-absorbing material that is at least partially transmissive to light in the UV spectrum. The method further comprises depositing a second sub-layer to be carried by the carrier body. The second sub-layer comprises a second light-absorbing material that is at least partially transmissive to light in the UV spectrum. The second light-absorbing material is configured to cause pulses of broadband light traveling through the carrier body and the first sub-layer to reflect within the light-absorbing layer to facilitate heat generation.

All features and advantages of the present disclosure will become apparent in the following detailed written description.

### BRIEF DESCRIPTION OF THE DRAWINGS

Objects and advantages of the present disclosure will best be understood by reference to the following detailed description of illustrative embodiments when read in conjunction with the accompanying drawings, wherein:

FIG. 1 is a flow diagram of a method for forming a reusable carrier, according to one embodiment;

FIG. 1A is a diagram of a reusable carrier made by the method depicted in FIG. 1;

FIG. 2 is a flow diagram of a method for attaching and detaching a wafer from a carrier, according to one embodiment;

FIG. 2A is a diagram of a carrier stack made by the method depicted in FIG. 2;

FIG. 2B shows the reusable carrier being released from the wafer from FIG. 2A;

FIG. 3 is a block diagram of an apparatus for attaching and detaching a wafer from a carrier, according to one embodiment;

FIG. 4 illustrates a vacuum table holding down a carrier stack, according to one embodiment; and

FIG. 5 is a diagram of a reusable carrier in accordance with another embodiment.

### DETAILED DESCRIPTION

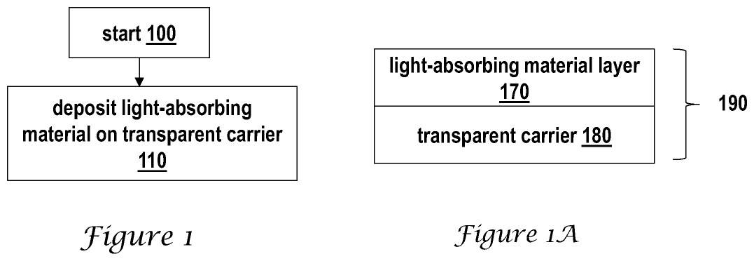

Before any attaching (bonding) and detaching (debonding) of electronics structures (e.g., wafers, chips, electronics components, electronics devices, etc.) can be performed, a reusable carrier needs to be made for such a purpose. Referring now to the drawings, and in particular to FIG. 1, there is depicted a flow diagram of a method for forming a reusable carrier, according to one embodiment. Starting at block 100, a layer 170 of partially transparent light-absorbing material (LAM) (generally, a “light-absorbing layer”) is deposited on a transparent carrier 180 (or a “carrier body”), as shown in block 110. Transparent carrier 180 is preferably rigid and is thermally stable beyond 400 °C. In addition, transparent carrier 180 is preferably transparent to most (e.g., greater than 50%) of the light emitted by a flashlamp that is a broadband emission from 200 nm to 1,100 nm. It will therefore be appreciated that “transparent,” as used herein, denotes a relative capacity to transmit some amount of light, rather than having absolute transparency. Transparent carrier 180 can be round or in the form of a rectangular panel, etc. Transparent carrier 180 can be made of glass. Examples of glass include Eagle XG glass made by Corning, Inc. or D263 glass made by Schott Glass, Inc. Transparent carrier 180 may also be made of quartz or a ceramic material such as an oxide (e.g., sapphire), nitride, or carbide (e.g., SiC), or a high-temperature polymer. It will be appreciated that the transparent carrier 180 may be a composite structure, such as including a carrier body (e.g., glass, quartz, ceramic, oxide, carbide, etc.) and one or more carrier layers thereon.

LAM layer 170 (or a portion (e.g., sublayer) thereof) can be deposited on transparent carrier 180 via a variety of additive techniques, including thermal evaporation, sputtering, CVD, PECVD, ALD, or other vacuum techniques. The LAM layer 170 (or a portion (e.g., sublayer) thereof) may also be deposited with wet processing techniques such as spin coating, printing, etc. Transparent carrier 180 and LAM layer 170 (together with additional, optional components or layers such as a light-filtering layer that transmits light in at least the UV wavelength spectrum) form a carrier stack or assembly 190, as shown in FIG. 1A. It will be appreciated that other layers may be present between the carrier 180 and the LAM layer 170 by which the carrier supports the LAM layer. Desirably, LAM layer 170 is approximately 1 to 2,000 nm thick and can transmit 0.1% to 20% of light within a wavelength range of 150 nm to 1,500 nm, which includes ultra-violet (UV) light. LAM layer 170 may include metals (such as tungsten, titanium, molybdenum, niobium, etc.), metal alloys (such as titanium-tungsten), ceramics (such as oxides, nitrides, and carbides), polymers, and/or other materials including carbon (such as amorphous carbon, diamondlike carbon, graphene, etc.). LAM layer 170 (broadly, at least a portion (e.g., sublayer) thereof) is desirably made of high-temperature material(s) that is/are stable at a temperature beyond 400 °C such that the LAM layer (or portion thereof) is reusable with the carrier 180 in multiple bond/debond cycles. In addition, LAM layer 170 has a coefficient of thermal expansion (CTE) within 12×10⁻⁶/°C, or more desirably within 9×10⁻⁶/°C of the material of transparent carrier 180. Desirably, LAM layer 170 is partially transparent to light, including UV light (broadly, a predetermined light wavelength range), but is configured to be absorptive of light in other wavelengths of the light emitted by a flashlamp (or other designated light source). Desirably, LAM layer 170 can transmit 0.1% to 20% of light within a wavelength range of 150 to 500 nm. In some embodiments, the LAM layer 170 (broadly, at least a portion (e.g., sublayer) thereof) is configured to degrade or be destroyed by the debonding process (or otherwise rendered damaged by the debonding process) such that the LAM layer (or portion (e.g., sublayer) thereof) is not reusable with the carrier 180. Other configurations can be used without departing from the scope of the present disclosure.

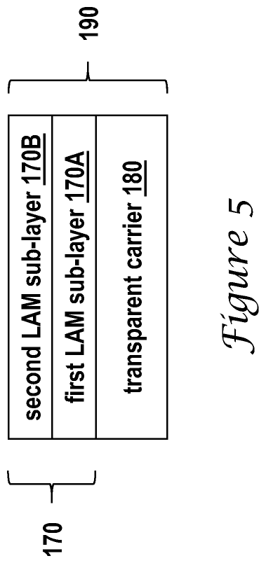

As is further shown in FIG. 5, the LAM layer 170 of carrier assembly 190 may be a composite layer comprising two or more layers (e.g., sublayers) of LAM stacked on or otherwise supported by the transparent carrier 180. For example, the LAM layer may comprise a first sub-layer 170A adjacent (on or near) the transparent carrier 180 and a second sub-layer 170B located away from the transparent carrier 180. It is contemplated that the first sub-layer 170A and the second sub-layer 170B each contain a respective LAM that is at least partially transmissive to light, but that each sub-layer is additionally selected to be effective at absorbing light of at least some wavelengths. For example, the first sub-layer 170A can comprise metallic materials such as tungsten, titanium, chromium, and/or similar metals and/or alloys (broadly, absorber materials). The first sub-layer 170A can have a thickness of up to about 2 microns, desirably up to about 50 nm, and desirably between about 5 nm and about 30 nm. The second sub-layer 170B can comprise a different material. For example, the second sub-layer 170B may comprise a ceramic, such as TiN, Si, SiC, SiN, Nb₂O₅, SiOₓ, and/or other materials that cause some amount of light to reflect at a boundary between the first sub-layer 170A and the second sub-layer 170B (broadly, light-trapping absorber materials). The second sub-layer can 170B have a thickness of up to about 2 microns, desirably up to about 50 nm, and desirably between about 20 nm and about 50 nm. The composite LAM layer 170 provides two different light transmissive/absorptive profiles, which can be used to enhance light transmissivity in one or more target wavelength ranges (e.g., UV) and absorptivity in certain other target wavelength ranges (e.g., infrared and one or more portions of the visible light spectrum). In one example, the first sub-layer 170A is configured to provide partial light transmission in a range of wavelengths (e.g., a range of UV wavelengths) different from wavelengths transmitted by the second sub-layer 170B. Accordingly, the two sub-layers allow the LAM layer to function as a filter that facilitates selective transmission of a peak working light wavelength (e.g., a desired range in the UV spectrum suitable for curing processes). Additionally, the configuration of the first sub-layer 170A and the second sub-layer 170B can promote enhanced absorption in the LAM layer 170 in different (e.g., non-UV) wavelengths, such as the visible and near-infrared (or NIR) regions of the electromagnetic spectrum. Light absorption can be enhanced by light that is reflected (e.g., reflected multiple times) at the boundary between the first sub-layer 170A and the second sub-layer 170B when incoherent light is transmitted through the carrier 180 and the first sub-layer 170A. When pulses of light undergo multiple reflections within the LAM layer 170, the opportunity for light to be absorbed by the light-absorbing materials in the LAM layer 170 increases substantially. Accordingly, the differences in composition of the first and second sub-layers 170A and 170B can provide a beneficial light-trapping or optical cavity effect that facilitates heat generation for debonding. The dual configuration of first and second sub-layers 170A and 170B can simplify and/or enhance energy efficiency and debonding thresholds of the manufacturing process for the carrier assembly 190 compared to complex single-layer compositions with similar light-absorptive and band pass filtering characteristics, can reduce manufacturing costs associated therewith, and/or can be used to provide reduced and/or more reliable bonding forces when electronics structures are temporarily carried by the carrier while providing desired amounts of light transmission (e.g., for curing) and light absorption (e.g., for debonding). Other configurations can be used without departing from the scope of the present disclosure. For example, it will be appreciated that three or more LAM layers could be used, such as to provide further related enhancements to filtering (e.g., to provide a dichroic or multi-band filtering effect) or absorbance in accordance with the same principles.

After carrier assembly 190 has been made, carrier assembly 190 can be utilized to attach to an electronics structure (e.g., wafer) with an adhesive disposed between them in order to process the electronics structure. After the electronics structure processing has been completed, carrier assembly 190 is detached from the electronics structure. Carrier assembly 190 can then be cleaned and be utilized again for another wafer. In some embodiments carrier assembly 190 (or one or more portions thereof) is not reusable.

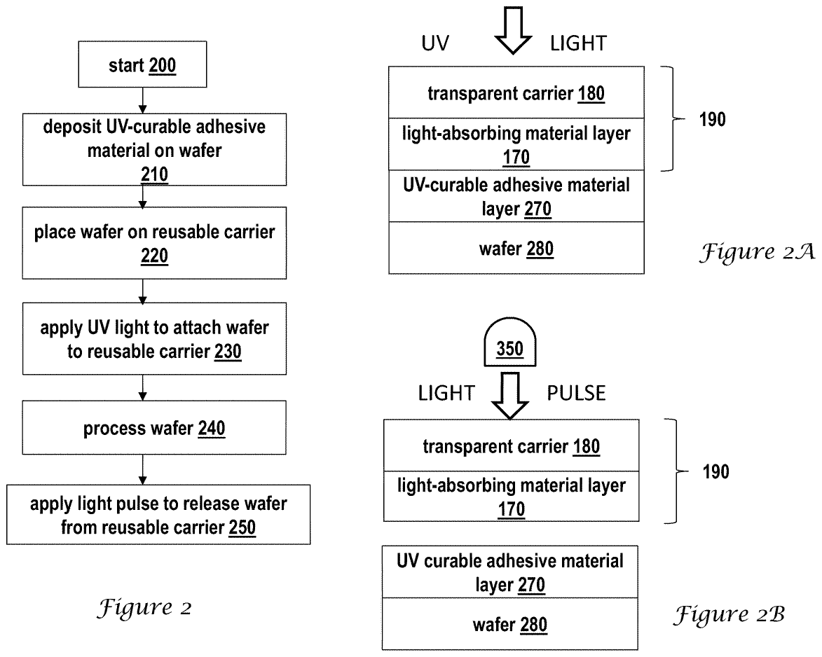

With reference now to FIG. 2, there is depicted a method for attaching carrier assembly 190 to an electronics structure (e.g., wafer) and for detaching carrier assembly 190 from the electronics structure, according to one embodiment. Like carrier assembly 190, the wafer (and/or other electronics structure) can be round or in the form of a rectangular panel, etc. The wafer may be a semiconductor, such as silicon or gallium arsenide. The wafer may also be glass, quartz, ceramic, polymer, or a composite structure.

Starting at block 200, a layer 270 of UV-curable adhesive is disposed on a wafer 280 (and/or other electronics structure), as shown in block 210. Next, wafer 280 is placed on reusable carrier 190, as depicted in block 220, such that UV-curable adhesive layer 270 comes into contact with LAM layer 170 in order to form a carrier stack, as shown in FIG. 2A. Alternatively, UV-curable adhesive can be disposed on LAM layer 170 of carrier assembly 190 and wafer 280 can then be placed on the UV-curable adhesive in order to form a carrier stack. UV-curable adhesive 270 may be deposited on wafer 280 using a variety of techniques. This includes directly depositing in liquid form onto carrier assembly 190 or wafer 280 using spin coating, casting, etc. After coating UV-curable adhesive layer 270, a drying step may also follow to remove excess solvent prior to placing reusable carrier 190 and wafer 280 adjacent to each other. UV-curable adhesive layer 270 may also be a multilayer UV-curable adhesive layer. This may be cast separately in the form of a self-supporting film before being applied directly to either carrier assembly 190 or wafer 280 and prior to placing them adjacent to each other. In that case, UV-curable adhesive layer 270 may be composed of two layers of UV-curable adhesive with an additional polymeric layer disposed between them to maintain dimensional stability of the self-supporting adhesive film. In the case of a multilayer UV-curable adhesive, it is required that each layer, including the central polymeric layer, is at least partially transparent to the curing light for UV-curing to be performed from the carrier side of the temporarily bonded stack. To cure all the layers of the adhesive film via UV light, each layer desirably is at least partially transparent to the UV-curing source.

In order to cure UV-curable adhesive layer 270, UV light from a UV source is directed from the side of transparent carrier 180 through LAM layer 170, as shown in block 230. The UV light can be light between 150 nm and 500 nm. The source of UV light can be a light-emitting diode, a mercury arc lamp, an excimer lamp, a flashlamp, a laser, etc. At this point, carrier assembly 190 is adhered to wafer 280, as depicted in FIG. 2A.

After wafer 280 has been secured to reusable carrier 190, the back-side of wafer 280 can be processed (or other electronics structure processing can be performed), as depicted in block 240. The processing may include wafer thinning, redistribution layer (RDL) buildup, deep reactive ion etching (DRIE), photolithography, sputtering, via formation, plating, device building, etc.

After all the wafer processing has been completed on wafer 280, wafer 280 is now ready to be detached (debonded) from carrier assembly 190 (which includes transparent carrier 180 and LAM layer 170). As such, a light pulse is sent from a light source (e.g., flashlamp) 300 from the side of transparent carrier 180 to heat up LAM layer 170 in order to detach wafer 280 from carrier assembly 190, as shown in block 250.

As shown in FIG. 2B, carrier assembly 190 (which includes transparent carrier 180 and LAM layer 170) is detached from wafer 280 such that the carrier assembly 190 is reusable. Carrier assembly 190 is then cleaned and is ready to be reused. In other words, transparent carrier 180 along with LAM layer 170 are reusable. Other configurations can be used without departing from the scope of the present disclosure. For example, in other embodiments, the carrier assembly 190 or a portion thereof is not reusable. For example, one or more layers of the carrier assembly 190 (e.g., the LAM layer or a sublayer thereof) is damaged in debonding. In some examples, such damaged layer(s) facilitate separation of the electronics structure from the carrier 180. In such instances, the carrier 180 can be reusable after refurbishing.

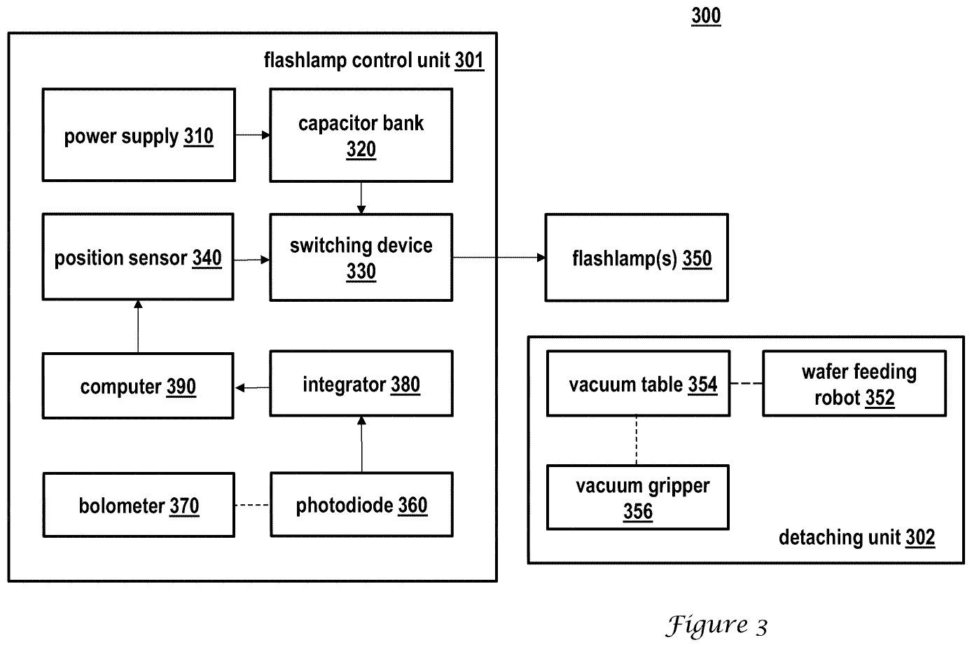

Referring now to FIG. 3, there is depicted a block diagram of an apparatus for performing detachment of a wafer from a carrier, according to one embodiment. As shown, an apparatus 300 includes a flashlamp (broadly, light source) control unit 301 and detaching unit 302. Flashlamp control unit 301 includes a capacitor-bank-charging power supply 310, a capacitor bank 320, an insulated gate barrier transistor (IGBT)-based switching device 330, a position sensor 340, a photodiode 360, a bolometer 370, an integrator 380, and a computer 390. Computer 390 includes a processor and various storage devices that are well-known to those skilled in the art. The capacitors in capacitor bank 320 are, for example, electrolytic capacitors. The capacitors in capacitor bank 320 may also be pulse discharge capacitors. Capacitor bank 320 may alternatively be switched with a silicon-controlled rectifier (SCR) switching device.

Capacitor bank 320 can be charged by capacitor-bank-charging power supply 310. Current from capacitor bank 320 is then discharged into flashlamp 350 via IGBT-based switching device 330 while IGBT-based switching device 330 is being switched on-and-off by position sensor 340 during the discharge. Position sensor 340 controls the gating of IGBT-based switching device 330 that, in turn, controls the switching of the discharge. The on-and-off switching of IGBT-based switching device 330 is intended to modulate the current flow from capacitor bank 320 to flashlamp(s) 350, which in turn switches flashlamp(s) 350 on-and-off. In other words, the switching of light pulses emitted by flashlamp(s) 350 is dictated by position sensor 340. Other configurations of illumination apparatus can be used without departing from the scope of the present disclosure.

If the area of flashlamp illumination is smaller than the size of carrier stack, multiple exposures of light pulse are needed to debond the entire wafer. In that case, the flashlamp head may be indexed relative to the carrier stack to illuminate a portion of the carrier stack until the entire carrier stack has been exposed. The conveyance may be in two dimensions (e.g., x-y) to cover the entire bonded wafer stack and the illuminations may be somewhat overlapped. For example, in the case when the flashlamp illumination area is approximately 75 mm×150 mm, 18-23 pulses of light may be needed to debond a 300 mm diameter wafer, but only 2 pulses of light may be needed to debond a 100 mm wafer.

Detaching unit 302 includes a wafer feeding robot 352, a vacuum table 354, and a vacuum gripper 356.

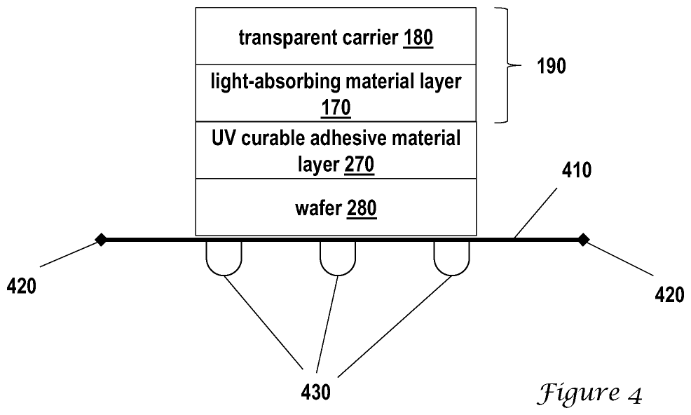

Prior to detaching, a dicing tape 410 may be attached to bonded wafer stack with film frame 420 to form a bonded wafer assembly, as shown in FIG. 4. Wafer feeding robot 352 conveys the bonded wafer assembly to vacuum table 354. A vacuum is then applied on dicing tape 410 from vacuum table 354. Then, a light pulse from flashlamp 350 is utilized to illuminate the bonded wafer assembly from the side of transparent carrier 180 in order to detach processed wafer 280 from transparent carrier 180.

At the separation station, vacuum gripper 356 separates reusable carrier 190 from the bonded wafer assembly, while wafer 280 mounted on dicing tape 410 is being held down by vacuum table 354. Both reusable carrier 190 and wafer 280 on dicing tape 410 are conveyed to a cleaning station to remove any residual adhesive. Residual adhesive may be removed with a wet process via solvent or a dry process with plasma and/or may be peeled off mechanically.

At this point, wafer 280 is so fragile that the vacuum being applied to wafer 280 should be distributed across wafer 280 so as not to break it during removal. This may be accomplished with multiple suction cups 430 distributed across the surface of wafer 280, as depicted in FIG. 4. Alternatively, the vacuum may be applied by a distributed vacuum, such as a vacuum table with perforated holes. Vacuum table 354 may have a polymer on its surface so that wafer 280 is not damaged during handling. As an alternative to a vacuum table and a vacuum gripper, an electrostatic chuck and electrostatic gripper may be used instead. Other configurations can be used without departing from the scope of the present disclosure.

As has been described, the present disclosure provides a method for bonding and debonding electronics structures (e.g., wafers) during manufacturing. One novelty of the present disclosure is that the LAM layer can be reusable. Another novelty of the present disclosure is that a UV-curable material can be cured by transmitting light through the LAM layer. One advantage of the present disclosure is that the partial transparency of the LAM layer allows the ability to carefully align the reusable carrier and the wafer relative to each other. These and other points of novelty are apparent from the present disclosure.

While examples have been particularly shown and described, it will be understood by those skilled in the art that various changes in form and detail may be made therein without departing from the spirit and scope of the invention.

### OTHER STATEMENTS OF THE DISCLOSURE

The following are statements or features of invention described in the present disclosure. Some or all of the following statements may not be currently presented as claims. Nevertheless, the statements are believed to be patentable and may subsequently be presented as claims. Associated methods corresponding to the statements or apparatuses below, and products and apparatuses corresponding to the methods below, are also believed to be patentable and may subsequently be presented as claims. It is understood that the following statements may refer to and be supported by one, more than one, or all the embodiments described above

A1. A method for processing electronics structures, comprising:
providing a carrier stack, the carrier stack comprising:
   a carrier comprising a substantially transparent carrier body; a light-absorbing layer carried by the carrier body, the light-absorbing layer comprising a first light-absorbing material that is at least partially transmissive to light in a wavelength range, the light-absorbing layer comprising a second light-absorbing material that is at least partially transmissive to light in the wavelength range, the first light-absorbing material and the second light-absorbing material being configured to absorb light to generate heat; and
   an electronics structure temporarily bonded to the carrier stack with a curable adhesive; and
directing a pulse of light through the carrier body to facilitate separation of the electronics structure and carrier body by generating heat in the light-absorbing layer;
wherein the second light-absorbing material is configured to cause the light to reflect within the light-absorbing layer to facilitate heat generation.

A2. The method of statement A1, wherein providing the carrier stack comprises disposing the curable adhesive between the carrier stack and the electronics structure and at least partially curing the curable adhesive.

B1. A method for processing electronics structures, comprising:
providing a carrier comprising a substantially transparent carrier body and a light-absorbing layer carried by the carrier body, the light-absorbing layer comprising a first light-absorbing material that is at least partially transmissive to light in a range of light wavelengths, the light-absorbing layer comprising a second light-absorbing material that is at least partially transmissive to light in the range of light wavelengths;
disposing a light-curable adhesive between the light-absorbing layer and a surface of an electronics structure; and
curing the light-curable adhesive by directing light in the range through the carrier body and the light-absorbing layer;
wherein the light-absorbing layer is configured to cause at least a portion of a pulse of light transmitted through the carrier body to reflect within the light-absorbing layer to facilitate heat generation in the light-absorbing layer.

B2. The method of statement B1, further comprising debonding the electronics structure from the carrier by directing a pulse of light through the carrier body to facilitate separation of the electronics structure from the carrier, the pulse of light comprising light having at least one wavelength outside of the range.

C1. The method of any of the above statements, wherein the carrier body comprises quartz, glass, ceramic, or polymer.

C2. The method of any of the above statements, wherein the electronics structure comprises a wafer comprising semiconductor, glass, or polymer.

C3. The method of any of the above statements, wherein the first light-absorbing material is deposited on said transparent carrier body via a vacuum deposition process or a wet deposition process.

C4. The method of any of the above statements, wherein the light-absorbing layer comprises a first sub-layer comprising the first light-absorbing material and the light-absorbing layer comprises a second sub-layer comprising the second light-absorbing material, the first sub-layer defining a first surface facing the carrier body and a second surface facing the second sub-layer.

C5. The method of statement C4, wherein the first light-absorbing material comprises one or more metals and the second light-absorbing material comprises a ceramic.

C6. The method of any of the above statements, wherein the first light-absorbing material comprises at least one of a Ti—W alloy, Ti, W, or Cr.

C7. The method of statement C4, wherein the first sub-layer has a thickness of between about 5 nm and about 30 nm.

C8. The method of any of the above statements, wherein the second light-absorbing material comprises at least one of TiN, SiN, SiC, Nb₂O₅, SiOₓ, or Si.

C9. The method of statement C4, wherein the second sub-layer has a thickness of between about 20 nm and about 50 nm.

C10. The method of any of the above statements, further comprising reusing the carrier stack in a subsequent temporary bonding and debonding cycle.

D1. An electronics structure temporary carrier comprising:
a substantially transparent carrier body; and
a light-absorbing layer carried by the carrier body;
wherein the light-absorbing layer transmits 0.1% to 20% of light within a wavelength range of about 150 nm to about 500 nm;
wherein the light-absorbing layer comprises a first sub-layer comprising a first light-absorbing material that is at least partially transmissive to light in the UV spectrum and a second sub-layer comprising a second light-absorbing material different from the first light-absorbing material, the first sub-layer defining a first surface facing the carrier body and a second surface facing the second sub-layer; and
wherein the second light-absorbing material is configured to cause a pulse of light traveling through the carrier body and the first sub-layer that is outside the UV spectrum to reflect within the light-absorbing layer to facilitate heat generation.

D2. The carrier of statement D1, wherein the carrier body and the light-absorbing layer are configured to be reusable in multiple temporary bond and debond cycles.

D3. The carrier of any of statements D1 through D2, wherein the first light-absorbing material comprises one or more metals and the second light-absorbing material comprises a ceramic.

D4. The carrier of any of statements D1 through D3, wherein the first LAM comprises at least one of a Ti-W alloy, Ti, W, or Cr.

D5. The carrier of any of statements D1 through D4, wherein the first sub-layer has a thickness of between about 5 nm and about 30 nm

D6. The carrier of any of statements D1 through D5, wherein the second light-absorbing material comprises one of TiN, SiN, SiC, Nb₂O₅, SiOₓ, or Si.

D7. The carrier of any of statements D1 through D6, wherein the second sub-layer has a thickness of between about 20 nm and about 50 nm.

D8. The carrier of any of statements D1 through D7, wherein the carrier body comprises quartz, glass, ceramic, or polymer.

D9. The carrier of any of statements D1 through D8, wherein each of the first light-absorbing material and the second light-absorbing material is stable at a temperature beyond 400 °C and has a coefficient of thermal expansion that is within 12×10⁻⁶/°C of the carrier body.

D10. A stack comprising the carrier of any of statements D1 through D9 and an electronics structure, the electronics structure being releasably bonded to the light-absorbing layer via a UV-curable adhesive.

E1. A method of forming a carrier adapted for temporarily carrying an electronics structure for manufacturing, the method comprising:
providing a substantially transparent carrier body;
depositing a first sub-layer to be carried by carrier body, the first sub-layer comprising a first light-absorbing material that is at least partially transmissive to light in the UV spectrum; and
depositing a second sub-layer to be carried by the carrier body, the second sub-layer comprising a second light-absorbing material that is at least partially transmissive to light in the UV spectrum;
   wherein the second light-absorbing material is configured to cause pulses of broadband light traveling through the carrier body and the first sub-layer to reflect within the light-absorbing layer to facilitate heat generation.

F1. A method for processing electronics structures, comprising:
providing a carrier stack, the carrier stack comprising:
   a carrier comprising a substantially transparent carrier body;
   a light-absorbing layer carried by the carrier body, the light-absorbing layer comprising a first light-absorbing material that is at least partially transmissive to light in a predetermined wavelength range and a second light-absorbing material that is at least partially transmissive to light in the predetermined wavelength range, the first light-absorbing material and the second light-absorbing material being configured to absorb light to generate heat; and
   an electronics structure temporarily bonded to the reusable carrier with a curable adhesive; and
directing a pulse of broadband light through the transparent body to facilitate separation of the electronics structure from the reusable carrier by generating heat in the light-absorbing layer;
wherein the second light-absorbing material is configured to prevent substantially all wavelengths of the broadband light outside of the predetermined wavelength range from passing into the adhesive.

G1. A method for attaching and detaching electronics structures, said method comprising:
providing a reusable carrier comprising a transparent carrier body and a light-absorbing layer carried by the transparent carrier body, the light-absorbing layer comprising a light-absorbing material (LAM) that is at least partially transmissive to light in the UV spectrum;
disposing a UV light-curable adhesive on an electronics structure;
placing said electronics structure on said reusable carrier with said light-absorbing layer in contact with said UV light-curable adhesive to form a carrier stack;
directing a UV light through said transparent carrier and said light-absorbing layer in order to cure said UV light-curable adhesive;
processing said electronics structure; and
sending a light pulse through said transparent carrier body toward said light-absorbing layer to facilitate separation of said electronics structure from said reusable carrier.

G2. A method for attaching and detaching electronics structures, said method comprising:
providing a reusable carrier comprising a transparent carrier body and a light-absorbing layer carried by the transparent carrier body, the light-absorbing layer comprising a light-absorbing material (LAM) that is at least partially transmissive to light in a predetermined spectrum of light wavelengths;
disposing a light-curable adhesive on said partially light-absorbing layer of said reusable carrier;
placing an electronics structure on said light-curable adhesive to form a carrier stack;
directing a light comprising light in the predetermined spectrum through said reusable carrier and said light-absorbing layer in order to cure said light-curable adhesive;
processing said electronics structure; and
sending a plurality of light pulses through said transparent carrier body toward said light-absorbing layer to detach said electronics structure from said transparent carrier.

G3. The method of any of statements G1 through G2, wherein said transparent carrier body comprises quartz, glass, ceramic, or polymer.

G4. The method of any of statements G1 through G3, wherein said LAM includes metal, ceramic, carbon, or polymer.

G5. The method of any of statements G1 through G4, wherein said electronics structure comprises a wafer made of semiconductor, glass, or polymer.

G6. The method of any of statements G1 through G5, wherein said predetermined spectrum of light wavelengths comprises UV light.

G7. The method of any of statements G1 through G6, wherein said light-absorbing layer is deposited on said transparent carrier body via a vacuum deposition or a wet deposition process.

G8. The method of any of statements G1 through G7, wherein said sending a light pulse further includes sending a light pulse from a flashlamp through said transparent carrier body.

G9. The method of any of statements G1 through G8, wherein said method further includes cleaning said transparent carrier body and said partially transparent LAM on said transparent carrier body for reuse.

G10. The method of any of statements G1 through G9, wherein said light-absorbing layer comprises a first sub-layer comprising the LAM that is at least partially transmissive to light in the UV spectrum and a second sub-layer comprising a second LAM different from the LAM that is at least partially transmissive to light in the UV spectrum, the first sub-layer defining a first surface facing the carrier body and a second surface facing the second sub-layer.

G11. The method of statement G10, wherein the LAM of the first layer is configured to absorb a majority of light in portions of the broadband light spectrum other than the UV range, and wherein said second LAM of the second sub-layer is configured to facilitate the selective transmission of light in the UV range by forming a dichroic filter with the first sub-layer.

G12. The method of statement G10, wherein the LAM of the first layer comprises one or more metals and the second LAM of the second layer comprises a ceramic.

G13. The method of statement G10, wherein the LAM of the first sub-layer comprises at least one of a Ti—W alloy, Ti, W, or Cr.

G14. The method of statement G10, wherein the first sub-layer has a thickness of between about 5 nm and about 30 nm.

G15. The method of statement G10, wherein the second LAM of the second sub-layer comprises at least one of TiN, SiN, SiC, Nb₂O₅, SiOₓ, or Si.

G16. The method of statement G10, wherein the second sub-layer has a thickness of between about 20 nm and about 50 nm.

H1. A reusable carrier adapted for photonic thermal processing of an electronics structure carried thereon, the carrier comprising:
a substantially transparent carrier body; and
a light-absorbing layer deposited on a surface of said substantially transparent carrier body, wherein said light-absorbing layer transmits 0.1% to 20% of light within a wavelength range of about 150 nm to about 500 nm, and wherein said substantially transparent carrier body and said light-absorbing layer are cleanable for reuse.

H2. The carrier of statement H1, wherein said light-absorbing layer comprises a first sub-layer comprising a first LAM that is at least partially transmissive to light in the UV spectrum and a second sub-layer comprising a second LAM different from the first LAM, the first sub-layer defining a first surface facing the carrier body and a second surface facing the second sub-layer.

H3. The carrier of any of statements H1 through H2, wherein the first LAM is configured to absorb a majority of light in portions of the broadband light spectrum other than the UV range, and wherein said second LAM is configured to facilitate the selective transmission of light in the UV range by forming a dichroic filter with the first sub-layer.

H4. The carrier of any of statements H1 through H3, wherein the first LAM comprises one or more metals and the second LAM of the second layer comprises a ceramic.

H5. The carrier of any of statements H1 through H4, wherein the first LAM comprises at least one of a Ti—W alloy, Ti, W, or Cr.

H6. The carrier of any of statements H1 through H5, wherein the first sub-layer has a thickness of between about 5nm and about 30nm.

H7. The carrier of any of statements H1 through H6, wherein the second LAM comprises one of TiN, SiN, SiC, Nb₂O₅, SiOₓ, or Si.

H8. The carrier of any of statements H1 through H7, wherein the second sub-layer has a thickness of between about 20 nm and about 50 nm.

H9. The carrier of any of statements H1 through H8, wherein said transparent carrier body comprises quartz, glass, ceramic, or polymer.

H10. The carrier of any of statements H1 through H9, wherein said light-absorbing layer includes metal, ceramic, carbon or polymer.

H11. The carrier of any of statements H1 through H10, wherein said light-absorbing layer comprises a light-absorbing material (LAM) that is stable at a temperature beyond 400 °C and has a coefficient of thermal expansion that is within 12×10⁻⁶/°C of said transparent carrier.

What is claimed is:

1. A method for processing electronics structures, comprising:
providing a carrier stack, the carrier stack comprising:
a carrier comprising a substantially transparent carrier body;
a light-absorbing layer carried by the carrier body, the light-absorbing layer comprising a first light-absorbing material that is at least partially transmissive to light in a wavelength range, the light-absorbing layer comprising a second light-absorbing material that is at least partially transmissive to light in the wavelength range, the first light-absorbing material and the second light-absorbing material being configured to absorb light to generate heat; and
an electronics structure temporarily bonded to the carrier stack with a curable adhesive; and
directing a pulse of light through the carrier body to facilitate separation of the electronics structure and carrier body by generating heat in the light-absorbing layer;
wherein the second light-absorbing material is configured to cause the light to reflect within the light-absorbing layer to facilitate heat generation.

2. The method of claim 1, wherein the carrier body comprises quartz, glass, ceramic, or polymer.

3. The method of claim 1, wherein the electronics structure comprises a wafer comprising semiconductor, glass, or polymer.

4. The method of claim 1, wherein the first light-absorbing material is deposited on said transparent carrier body via a vacuum deposition process or a wet deposition process.

5. The method of claim 1, wherein the light-absorbing layer comprises a first sub-layer comprising the first light-absorbing material and the light-absorbing layer comprises a second sub-layer comprising the second light-absorbing material, the first sub-layer defining a first surface facing the carrier body and a second surface facing the second sub-layer.

6. The method of claim 5, wherein the first light-absorbing material comprises one or more metals and the second light-absorbing material comprises a ceramic.

7. The method of claim 5, wherein the first light-absorbing material comprises at least one of a Ti—W alloy, Ti, W, or Cr.

8. The method of claim 7, wherein the first sub-layer has a thickness of between about 5 nm and about 30 nm.

9. The method of claim 5, wherein the second light-absorbing material comprises at least one of TiN, SiN, SiC, Nb₂O₅, SiOₓ, or Si.

10. The method of claim 9, wherein the second sub-layer has a thickness of between about 20 nm and about 50 nm.

11. The method of claim 1, further comprising reusing the carrier stack in a subsequent temporary bonding and debonding cycle.

12. The method of claim 1, wherein providing the carrier stack comprises disposing the curable adhesive between the carrier stack and the electronics structure and at least partially curing the curable adhesive.

13. A method for processing electronics structures, comprising:
providing a carrier comprising a substantially transparent carrier body and a light-absorbing layer carried by the carrier body, the light-absorbing layer comprising a first light-absorbing material that is at least partially transmissive to light in a range of light wavelengths, the light-absorbing layer comprising a second light-absorbing material that is at least partially transmissive to light in the range of light wavelengths;
disposing a light-curable adhesive between the light-absorbing layer and a surface of an electronics structure; and
curing the light-curable adhesive by directing light in the range through the carrier body and the light-absorbing layer;
wherein the light-absorbing layer is configured to cause at least a portion of a pulse of light transmitted through the carrier body to reflect within the light-absorbing layer to facilitate heat generation in the light-absorbing layer.

14. The method of claim 13, further comprising debonding the electronics structure from the carrier by directing a pulse of light through the carrier body to facilitate separation of the electronics structure from the carrier, the pulse of light comprising light having at least one wavelength outside of the range.

15. The method of claim 14, the method further reusing the carrier in a subsequent temporary bonding and debonding cycle.

16. The method of claim 13, wherein the range of light wavelengths comprises UV light.

17. The method of claim 13, wherein the light-absorbing layer comprises a first sub-layer comprising the first light-absorbing material and a second sub-layer comprising the second light-absorbing material, the first sub-layer defining a first surface facing the carrier body and a second surface facing the second sub-layer.

18. The method of claim 17, wherein the first light-absorbing material comprises at least one of a Ti—W alloy, Ti, W, or Cr.

19. The method of claim 17, wherein the second light-absorbing material comprises at least one of TiN, SiN, SiC, Nb₂O₅, SiOₓ, or Si.

20. An electronics structure temporary carrier comprising:
a substantially transparent carrier body; and
a light-absorbing layer carried by the carrier body;
wherein the light-absorbing layer transmits 0.1% to 20% of light within a wavelength range of about 150 nm to about 500 nm;
wherein the light-absorbing layer comprises a first sub-layer comprising a first light-absorbing material that is at least partially transmissive to light in the UV spectrum and a second sub-layer comprising a second light-absorbing material different from the first light-absorbing material, the first sub-layer defining a first surface facing the carrier body and a second surface facing the second sub-layer; and
wherein the second light-absorbing material is configured to cause a pulse of light traveling through the carrier body and the first sub-layer that is outside the UV spectrum to reflect within the light-absorbing layer to facilitate heat generation.

21. The carrier of claim 20, wherein the carrier body and the light-absorbing layer are configured to be reusable in multiple temporary bond and debond cycles.

22. The carrier of claim 20, wherein the first light-absorbing material comprises one or more metals and the second light-absorbing material comprises a ceramic.

23. The carrier of claim 20, wherein the first LAM comprises at least one of a Ti—W alloy, Ti, W, or Cr.

24. The carrier of claim 21, wherein the first sub-layer has a thickness of between about 5 nm and about 30 nm 25. The carrier of claim 20, wherein the second light-absorbing material comprises one of TiN, SiN, SiC, Nb₂O₅, SiOₓ, or Si.

26. The carrier of claim 25 wherein the second sub-layer has a thickness of between about 20 nm and about 50 nm.

27. The carrier of claim 20, wherein the carrier body comprises quartz, glass, ceramic, or polymer.

28. The carrier of claim 20, wherein each of the first light-absorbing material and the second light-absorbing material is stable at a temperature beyond 400 °C and has a coefficient of thermal expansion that is within 12×10⁻⁶/°C of the carrier body.

29. A stack comprising the carrier of claim 20 and an electronics structure, the electronics structure being releasably bonded to the light-absorbing layer via a UV-curable adhesive.

30. A method of forming a carrier adapted for temporarily carrying an electronics structure for manufacturing, the method comprising:
providing a substantially transparent carrier body;
depositing a first sub-layer to be carried by carrier body, the first sub-layer comprising a first light-absorbing material that is at least partially transmissive to light in the UV spectrum; and
depositing a second sub-layer to be carried by the carrier body, the second sub-layer comprising a second light-absorbing material that is at least partially transmissive to light in the UV spectrum;
wherein the second light-absorbing material is configured to cause pulses of broadband light traveling through the carrier body and the first sub-layer to reflect within the light-absorbing layer to facilitate heat generation.
